(19) United States
(12) Patent Application Publication
(10) Pub. No.: US 2009/0194804 A1
(43) Pub. Date: Aug. 6, 2009

(54) NON-VOLATILE MEMORY CELL

(75) Inventor: Bohumil Lojek, Colorado Springs, CO (US)

Correspondence Address: FISH & RICHARDSON P.C., PO BOX 1022, MINNEAPOLIS, MN, 55440-1022, US

(73) Assignee: ATMEL CORPORATION, San Jose, CA (US)

(21) Appl. No.: 12/025,224

(22) Filed: Feb. 4, 2008

(51) Int. Cl. H01L 27/115; H01L 21/8247

(52) U.S. Cl. 257/321; 438/258; 257/E27.103; 257/E21.691

(57) ABSTRACT

Disclosed herein are non-volatile cells and methods of manufacturing the same. The nonvolatile memory cells include a high voltage device, a low voltage device, and a memory cell formed on a semiconductor substrate. The high voltage device, low voltage device, and memory cell are all self-aligned by using the gates associated with each of the devices as a mask during formation of the respective sources and drains.

### BACKGROUND

This specification relates to semiconductor manufacturing.

Electronic devices are continually being developed that offer more performance while utilizing less power and in smaller packages. For example, portable computing devices have evolved into comprehensive data devices that integrate the features of phones, personal digital assistants (PDAs) and computers. As the capabilities of these devices increase, so do their memory and power requirements. The increasing memory requirements of electronic devices coupled with shrinking power budgets and packaging dimensions requires memory devices that offer more storage, with lower power consumption, and smaller physical dimensions. Additionally, many devices require high voltage logic, low voltage logic, and memory cells to be contained in the same package, requiring these devices to be manufactured on a common semiconductor substrate.

The placement of gates on the semiconductor substrate presents a challenge to such optimizations, however. Typically, there is some error, known as registration error, associated with the placement of gates on a semiconductor substrate during the manufacturing process. Accordingly, in some semiconductor devices, this registration error may limit device density.

### SUMMARY

Disclosed herein are non-volatile memory cells and methods of manufacturing the same. The nonvolatile memory cells, high voltage device, and low voltage device are formed on a semiconductor substrate. The high voltage device, low voltage device, and memory cell are all self-aligned by using the gates associated with each of the devices as a mask during formation of the respective sources and drains.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a block diagram of an example implementation of a self-aligned nonvolatile memory cell.

FIGS. 2A-2H are block diagrams illustrating an example implementation of fabrication of a self-aligned non-volatile cell.

FIG. 3 is a flow chart illustrating an example implementation of a process for manufacturing a self-aligned nonvolatile memory cell.

Like reference numbers and designations in the various drawings indicate like elements.

### DETAILED DESCRIPTION

### I. Self-Aligned Non-Volatile Memory Cell Example Structure

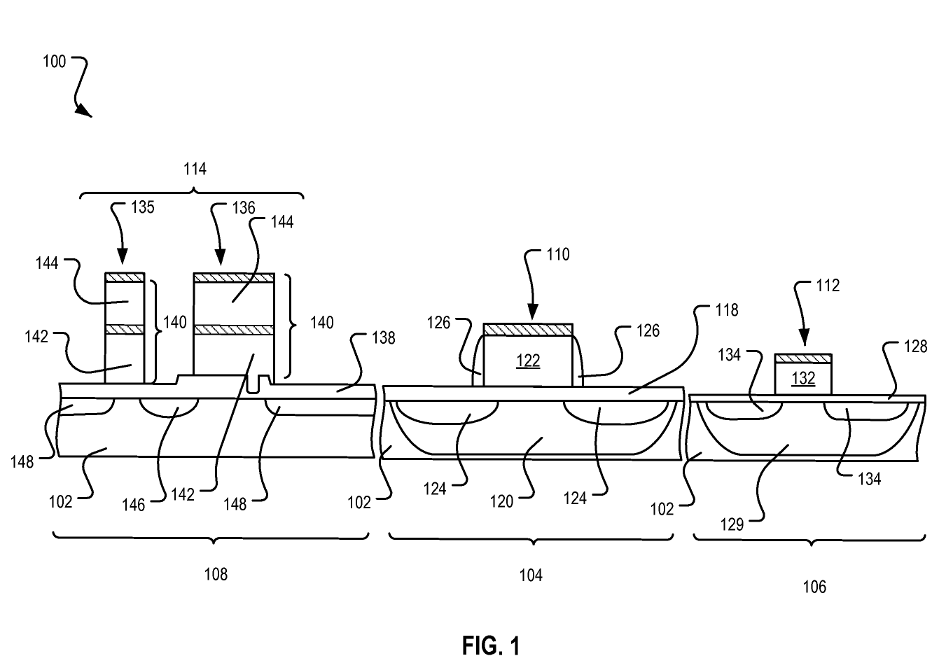

FIG. 1 is a block diagram of an example implementation of a self-aligned nonvolatile memory cell 100. The nonvolatile memory cell 100 has a semiconductor substrate 102. The semiconductor substrate 102 can be silicon or any other appropriate semiconductor material. The semiconductor substrate 102 has a high voltage device region 104, a low voltage device region 106, and a memory cell region 108. High voltage devices 110 are located in the high voltage device region 104, low voltage devices 112 are located in the low voltage device region 106, and memory cells 114 are located in the memory cell region 108. These devices are all formed on a single semiconductor substrate 102. In some implementations the high voltage devices 110, low voltage devices 112, and memory cells 114 all have self-aligned gates. MOSFET gates are self-aligned gates where the gate is formed prior to implantation of the well regions that define the source and the drain. When the gate is formed prior to implantation it operates as a mask causing the dopant to be implanted proximate to the sides of the gate but not beneath the gate. All of the devices described below can be implemented as p-type devices or n-type devices.

i. High Voltage Devices

The high voltage device 110 is a MOSFET device that can operate at 12-18V. The high voltage device 110 has a high voltage oxide layer 118 that is formed on the semiconductor substrate 102. The high voltage oxide layer 118 has a thickness of approximately 200 Å-300 Å. The high voltage oxide layer 118 can be silicon dioxide or any other appropriate oxide layer.

A high voltage device 110 can be manufactured, for example, as a p-type device. The p-type high voltage device 110 has a high voltage n-well 120. The n-well 120 can be formed in the semiconductor substrate 102 by ion implantation or any other method of adding dopants to a semiconductor substrate 102. A first gate 122 is located over the high voltage n-well 120. The first gate 122 operates as a control gate for the high voltage device 110. The first gate 122 can be polysilicon or any other appropriate conductive gate material.

Low voltage p-wells 124 are formed in the semiconductor substrate 102, proximate to the sides of the first gate 122. The low voltage p-wells 124 define the source and drain of a p-type high voltage device 110. The low voltage p-wells 124 are formed by adding dopants to the high voltage n-well 120. The dopants can be added to the high voltage n-well 120 by ion implantation or any other appropriate method for adding dopants to a high voltage n-well 120. The first gate 122 is a self-aligned gate because it is formed prior to the formation of the source and drain.

Spacers 126 are located adjacent to and connected to the first gate 122. The spacers 126 are formed from polysilicon or any other appropriate gate material. A p-type high voltage device 110 has been described, but the high voltage device 110 can also be manufactured as an n-type high voltage device 110.

ii. Low Voltage Devices

Each low voltage device 112 is a MOSFET device that can operate in a voltage range from approximately 1V-4V. The low voltage device 112 has a low voltage oxide layer 128 that is formed on the semiconductor substrate 102. The low voltage oxide layer 128 has a thickness ranging from approximately 18-90 Å. The low voltage oxide layer 128 can be silicon dioxide or any other appropriate oxide layer.

A low voltage device 112 can be manufactured, for example, as an n-type device. The n-type low voltage device 112 has a low voltage p-well 129 formed in the semiconductor substrate 102. The low voltage p-well 129 is formed by adding dopants to the semiconductor substrate 102. The dopants can be added by ion implantation or any other appropriate method for adding dopants to a semiconductor substrate 102. The low voltage p-well 129 is formed at the same time as the low voltage p-wells 124 that are formed in the high voltage n-well 120.

A second gate 132 is located over the low voltage p-well 129. The second gate 132 operates as a control gate for the low voltage device 112. The second gate 132 can be polysilicon or any other appropriate conductive gate material.

Source/drain (“S/D”) regions 134 are formed in the low voltage p-well 129 associated with the low voltage device 112. The S/D regions 134 are formed by adding dopants to the low voltage p-well 129. The dopants can be added by ion implantation or any other appropriate method for adding dopants to a semiconductor substrate 102. The second gate 132 is a self-aligned gate because it is formed prior to the formation of the source and drain of the low voltage device. An n-type low voltage device 112 has been described, but the low voltage device 112 can also be manufactured as a p-type low voltage device 112.

iii. Memory Cells

Each memory cell 114 includes a select transistor 135 and a memory transistor 136. The memory cell 114 has a structured oxide layer 138 having a thickness that varies from approximately 19 Å to approximately 280 Å. The structured oxide layer 138 can be silicon dioxide or any other appropriate oxide layer. The memory cell 114 can be manufactured, for example, as an n-type memory cell 114. The n-type memory cell 114 has n-regions that define the common source 146 and the drains 148 for the select transistor 135 and the memory transistor 136. The select transistor 135 and memory transistor 136 each have memory cell gates 140. The memory cell gates 140 each have a memory cell floating gate 142 and a memory cell control gate 144. The memory cell gates 140 are self-aligned gates because they are formed prior to the formation of the common source 146 and the drains 148 of the memory cell 114. An n-type memory cell 114 has been described, but the memory cell 114 can also be manufactured as a p-type memory cell 114.

### II. Fabrication

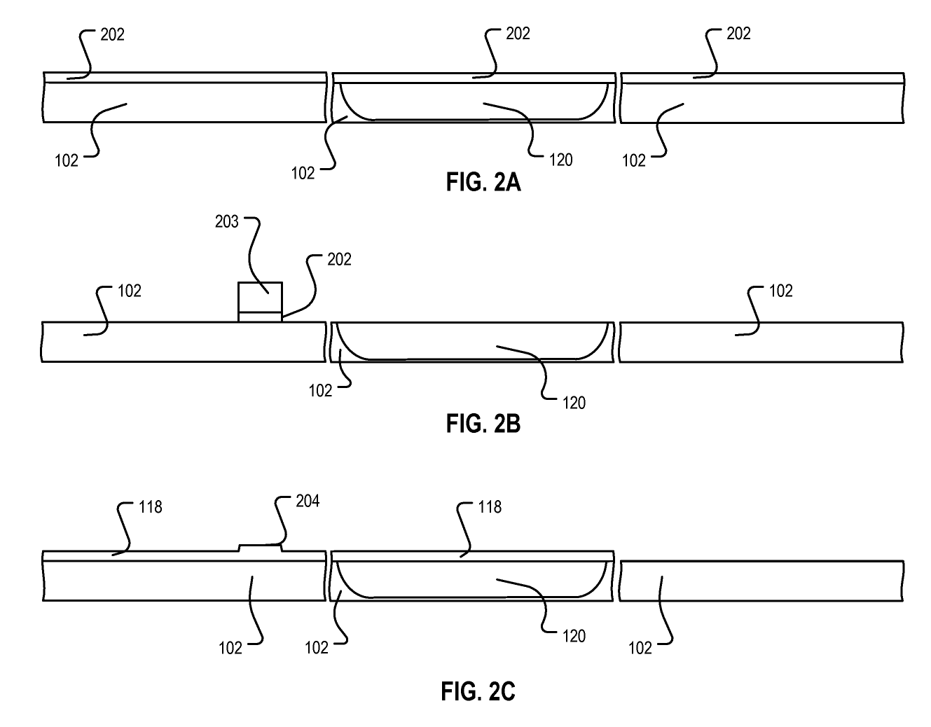

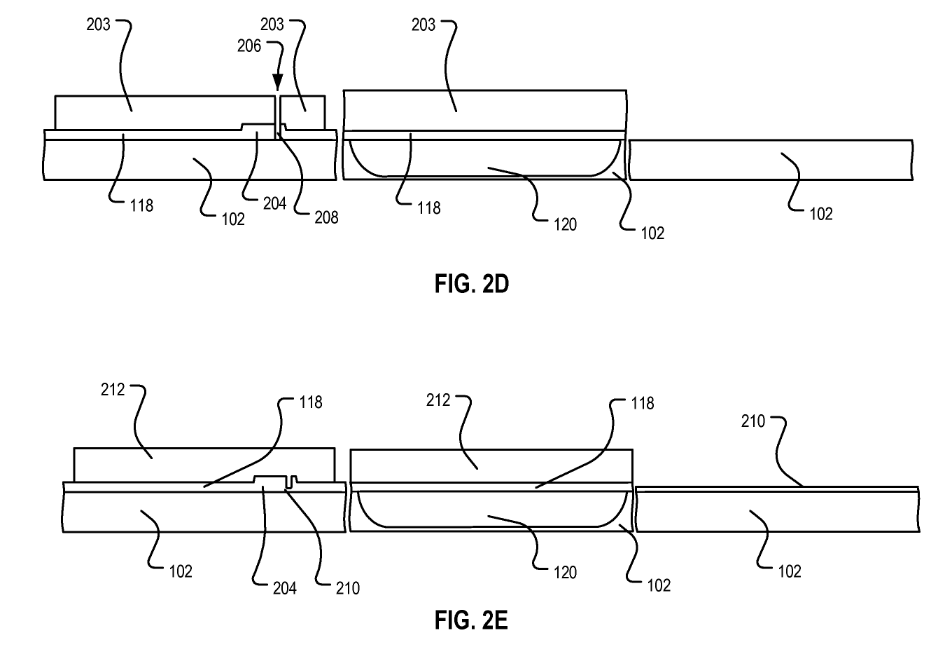

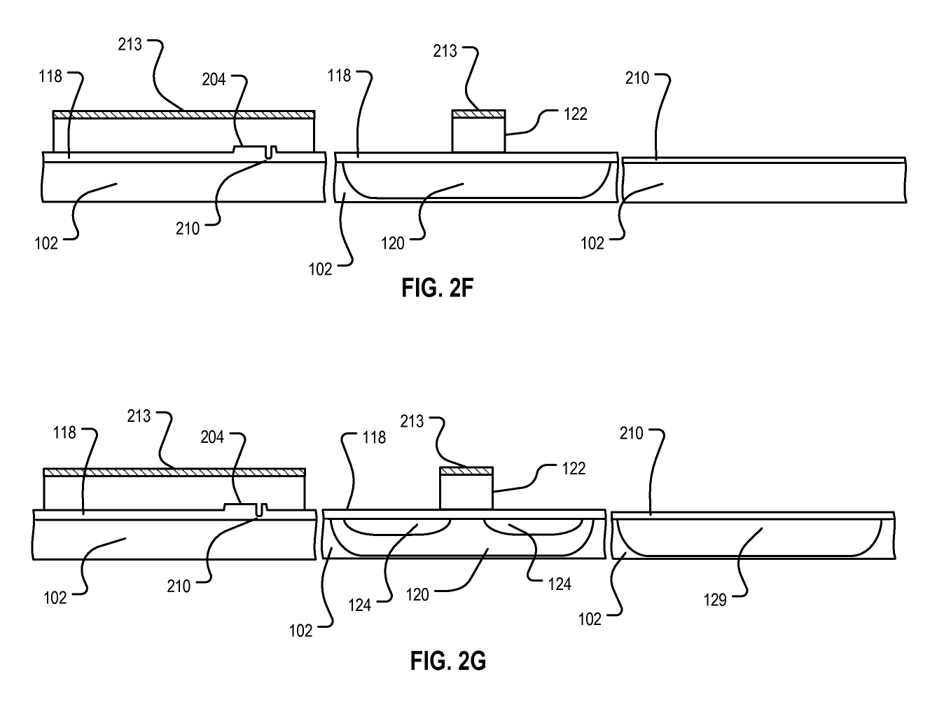

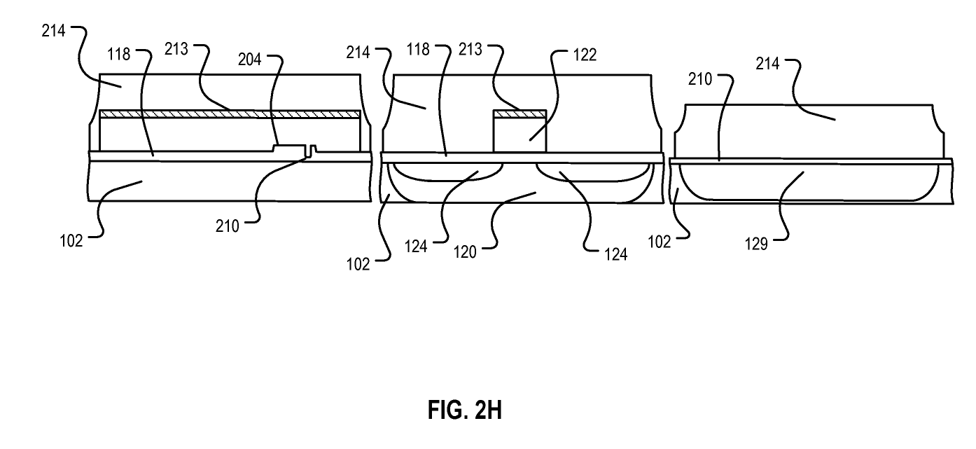

FIGS. 2A-2H are block diagrams illustrating an example implementation of fabrication of a self-aligned non-volatile cell 100. First, an initial oxide layer 202 is grown on the semiconductor substrate 102, as shown in FIG. 2A. The initial oxide layer 202 can be silicon dioxide or any other appropriate oxide layer. The initial oxide layer 202 can be formed by thermal oxidation of the semiconductor substrate 102 or any other appropriate method. The initial oxide layer 202 is grown to be approximately 250 Å-400 Å thick.

Photoresist 203 is applied to a portion of the initial oxide layer 202 that is located in the memory device region 108, as shown in FIG. 2B. A mask is used to selectively apply the photoresist 203 to the initial oxide layer 202. Once the photoresist 203 is applied, the initial oxide layer 202 is etched. The etching process removes the initial oxide layer 202 that is not protected by the photoresist 203. The photoresist is then removed.

A high voltage oxide layer 118 is grown on the semiconductor substrate 102. The high voltage oxide layer 118 is also grown on the remaining initial oxide layer 202 to create a raised oxide portion 204 in the memory device region 108, as shown in FIG. 2C. The high voltage oxide layer 118 does not grow as quickly on the initial oxide layer 202 as it does on the semiconductor substrate 102. Therefore, the high voltage oxide layer 118 that is grown on the semiconductor substrate 102 is approximately 220 Å thick, but the raised oxide portion 204 is approximately 280 Å thick.

Photoresist 203 is applied to protect the oxide layers formed in the memory cell region 108 and high voltage device region 104, as shown in FIG. 2D. A mask is used to apply the photoresist 203. The mask defines an opening 206 in the photoresist 203 over the raised oxide portion 204, as shown in FIG. 2D. An etching process is used to remove the unprotected portion of the raised oxide portion 204. The etching process results in a tunnel 208 defined in the raised oxide portion 204.

A low voltage oxide layer 210 is grown on the semiconductor substrate 102. The low voltage oxide layer can range from 19 Å-90 Å thick. After the low voltage oxide layer 210 is grown, the oxide layer for each of the regions of the semiconductor substrate 102 is complete and shown in FIG. 2E.

A first poly layer 212 is deposited in the memory cell region 108 and high voltage device region 104, as shown in FIG. 2E. The first poly layer 212 can be polysilicon or any other appropriate conductive gate material. The first poly layer 212 forms the floating gates of the memory cells 114 and the gates of the high voltage devices 110.

The first poly layer 212 is etched to form a first gate 122 in the high voltage region 104. A thin oxide layer 213 is formed on top of the first poly layer 212 remaining in the memory cell region 108 and the first gate 122, as shown in FIG. 2F. The etched first gate 122 formed in the high voltage device region 104 functions as the control gate for the high voltage device 110.

Low voltage p-wells 124 are used to form source and drain regions in the high voltage n-well 120. A low voltage p-well 129 is also formed in the low voltage device region 106 at the same time, as shown in FIG. 2G. The low voltage p-wells 124, 129 can be formed by adding dopants to the semiconductor substrate 102. The dopants can be added by ion implantation or any other appropriate manner. The first gate 122 in the high voltage device region 104 operates as a mask preventing dopants from being added to the semiconductor substrate 102 beneath the first gate 122. Therefore, the dopants will be added to the semiconductor substrate 102 adjacent to the first gate 122. Adding dopants to the semiconductor substrate 102 in this manner makes the first gate 122 (e.g., the control gate) for the high voltage device a self-aligned gate. Therefore, there is no registration error associated with the placement of the first gate 122. A mask is used during the implantation to prevent dopants from being added to the memory cell region 108 of the semiconductor substrate 102.

A second poly layer 214 is deposited in the high voltage device region 104, the low voltage device region 106, and the memory cell region 108, as shown in FIG. 2H. The second poly layer can be polysilicon or any other appropriate conductive gate material.

The second poly layer 214 in the low voltage device region 106 is etched to form a second gate 132. The second poly layer 214 is completely etched from the top of the first gate 122 in the high voltage device region 104. However, some of the second poly layer 214 will remain in the high voltage device region 104 after the etching process. The remaining portion of the second poly layer 214 defines spacers 126 that are adjacent to the first poly layer 212, as shown in FIG. 1.

The first poly layer 212 and the second poly layer 214 are both etched in a single etch process to form memory cell gates 140. The resulting memory cell gates 140 will have a memory cell floating gate 142 and a memory cell control gate 144. The memory cell floating gate 142 and the memory cell control gate 144 will have no registration error because the gates are formed during a single etching process.

After the gates have been formed in the low voltage device region 106 and the memory cell region 108, Sources and drains are formed in the low voltage device region 106 and the memory cell region 108. In some implementations, the sources and drains of the low voltage region 106 can be formed separately from the sources and drains of the memory cell region 108. The S/D regions 134 define the source and the drain for the low voltage device 112. The memory cell 114 can have sources and drains defined by a common source 146 and the drains 148. Dopants are added to the semiconductor substrate 102 at a position adjacent to the respective control gates to form the sources and drains. The dopants are added by ion implantation or any other appropriate method for adding dopants to a semiconductor substrate 102. The dopants can be added to the low voltage device region 106 and the memory cell region 108 at the same time. A mask is used to prevent the dopants from being added to the high voltage device region 104. The second gate 132 in the low voltage device region 106 and the memory cell gates 140 in the memory cell region 108 operate as masks to prevent dopants from being added to the semiconductor substrate 102 beneath the respective gates. Therefore, the second gates 132 and the memory cell gates 140 are self-aligned gates.

### III. Process

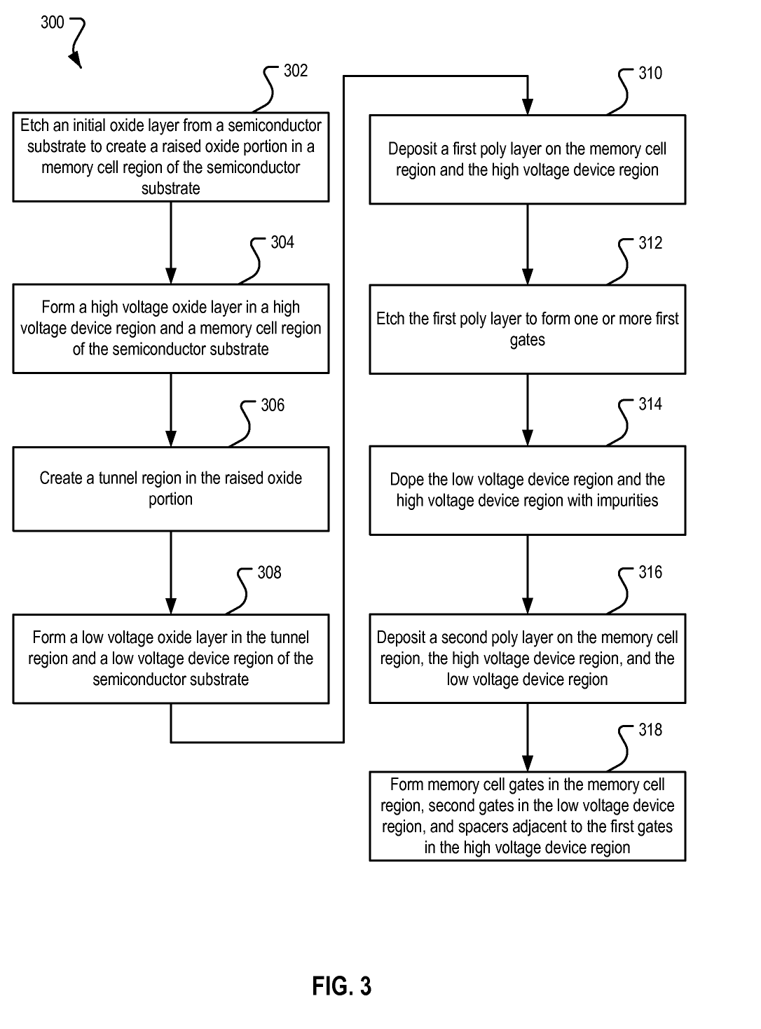

FIG. 3 is a flow chart illustrating an example implementation of a process for manufacturing a self-aligned nonvolatile memory cell. The process 300 can begin by etching an initial oxide layer from a semiconductor substrate to create a raised oxide portion in a memory cell region of the semiconductor substrate (302). The etching can be performed, for example, by covering the raised oxide portion 204 with photoresist 203 to prevent the etching from removing the raised oxide portion 204. The initial oxide layer 202 can be formed, for example, by growing an oxide layer (e.g., silicon dioxide) on a semiconductor substrate 102. The oxide layer can be grown, for example, by thermal oxidation of the semiconductor substrate 102 or any other appropriate process. The semiconductor substrate 102 can have a high voltage device region 104, a low voltage device region 106, and a memory cell region 108.

The process 300 also forms a high voltage oxide layer in a high voltage device region and a memory cell region of the semiconductor substrate (304). For example, the high voltage oxide layer 118 can be formed by growing an oxide layer (e.g., silicon dioxide). The high voltage oxide layer can be formed, for example, by thermal oxidation of the semiconductor substrate 102 or any other appropriate process.

The process 300 additionally creates a tunnel region in the raised oxide portion (306). The tunnel can be formed, for example, by first selectively depositing photoresist 203 on the semiconductor substrate 102, so that an opening 206 is defined over the raised oxide portion 118. Then the raised oxide portion 118 that is within the opening 206 is etched to create the tunnel 208.

Further, the process 300 forms a low voltage oxide layer in the tunnel region and a low voltage device region of the semiconductor substrate (308). The low voltage oxide layer 128 is formed for example, by growing an oxide layer (e.g., silicon dioxide) on the semiconductor substrate 102 by thermal oxidation of the semiconductor substrate 102 or any other appropriate process. The low voltage oxide layer can range in thickness from 19 Å-90 Å.

The process 300 continues by depositing a first poly layer on the memory cell region and the high voltage device region (310). The first poly layer can be any conductive gate material (e.g., polysilicon). A mask can be used to selectively deposit the first poly layer on the memory cell region and the high voltage device region.

The process 300 etches the first poly layer to form one or more first gates (312). For example, photoresist 203 can be selectively deposited on the first poly layer 212 to protect the first gates 122 from the etching process. The first gates 122 can be control gates for the high voltage devices 110 and an oversized floating poly for the memory cell 114.

Further, the process 300 dopes the low voltage device region and the high voltage device region with impurities (314). The doping can be performed, for example, by ion implantation or any other process appropriate for doping a semiconductor substrate 102. The first gates 122 prevent the impurities from being implanted to the semiconductor substrate 102 located beneath the first gates 122 and form the source and drain of the high voltage device. Therefore, the impurities are implanted in the semiconductor substrate 102 adjacent to the first gates 122 resulting in self-aligned first gates. A mask can be used to prevent the impurities from being implanted, for example, into memory device region 108.

The process 300 additionally deposits a second poly layer on the memory cell region, the high voltage device region, and the low voltage device region (316). The second poly layer can be any appropriate conductive gate material (e.g., polysilicon).

The process 300 also forms memory cell gates in the memory cell region, second gates in the low voltage device region, and spacers adjacent to the first gates in the high voltage device region (318). For example, the memory cell gates 140 are formed by etching the first poly layer 212 and the second poly layer 214, located in the memory cell region 108. The second gates 132 are formed by etching the second poly layer 214 located in the low voltage device region 106. The spacers 126 are the portion of the second poly layer 214 that remains adjacent to the first poly layer 212 when the second poly layer 214 is removed. The memory cell gates 140, second gates 132, and spacers 126 are all formed during the same etching process.

While this document contains many specific implementation details, these should not be construed as limitations on the scope what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Particular embodiments of the subject matter described in this specification have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results.

What is claimed is:

1. A method, comprising:
forming a structured oxide layer on a semiconductor substrate, the structured oxide layer formed in a memory cell region of the semiconductor substrate;
forming a high voltage oxide layer on the semiconductor substrate, the high voltage oxide layer formed in a high voltage device region of the semiconductor substrate;
forming a low voltage oxide layer on the semiconductor substrate the low voltage oxide layer formed in a low voltage device region of the semiconductor substrate; and
forming self aligned gates on the structured oxide layer, the high voltage oxide layer, and the low voltage oxide layer.

2. The method of claim 1, wherein forming the structured oxide layer comprises:
etching an initial oxide layer from a semiconductor substrate to create a raised oxide portion in a memory cell region of the semiconductor substrate; and
creating a tunnel region in the raised oxide portion.

3. The method of claim 2, wherein creating a tunnel region comprises:
depositing a photoresist layer on the semiconductor substrate; and
etching the raised oxide portion.

4. The method of claim 2, further comprising:
forming a low voltage oxide layer in the tunnel region and a low voltage device region of the semiconductor substrate.

5. The method of claim 1, wherein forming self aligned gates on the structured oxide layer, the high voltage oxide layer, and the low voltage oxide layer comprises:
depositing a first poly layer on the memory cell region and the high voltage device region; and
etching the first poly layer to form one or more first gates.

6. The method of claim 5, wherein etching the first poly layer to form one or more gates comprises etching the first poly layer to form one or more first gates in the high voltage device region.

7. The method of claim 5, further comprising:
depositing a second poly layer on the memory cell region, the high voltage device region, and the low voltage device region; and
forming memory cell gates in the memory cell region, second gates in the low voltage device region, and spacers adjacent to the first gates.

8. The method of claim 7, further comprising doping the high voltage device region with impurities, wherein the first gates are masks for the doping.

9. The method of claim 7, further comprising doping the low voltage device region with impurities, wherein the second gates function are masks for the doping.

10. The method of claim 7, further comprising doping the memory cell region with impurities, wherein the memory cell gates are masks for the doping.

11. The method of claim 7, wherein the forming memory cell gates comprises etching the first poly layer and the second poly layer to create floating gate devices.

12. The method of claim 7, wherein forming memory cell gates in the memory cell region, second gates in the low voltage device region, and spacers adjacent to the first gates comprises etching the first poly layer and the second poly layer in the memory cell region.

13. The method of claim 12, further comprising etching the second poly layer in the low voltage device region and the high voltage device region.

14. A method, comprising:
forming a structured oxide layer and a high voltage oxide layer on a semiconductor substrate, wherein the structured oxide layer is formed in a memory cell region of the substrate and the high voltage oxide layer is formed in a high voltage device region of the substrate;
depositing a first poly layer on the memory cell region and the high voltage device region;
forming a first gate in the high voltage device region;
forming a plurality of self-aligned high voltage source/drain regions with low voltage well implants in the high voltage device region using the first gate as a mask;
depositing a second poly layer on the memory cell region and the high voltage device region;
forming a plurality of memory cell gates in the memory cell region; and
removing the second poly layer from the high voltage device region.

15. The method of claim 14, wherein forming a structured oxide layer and a high voltage oxide layer comprises:
forming an initial oxide layer on the semiconductor substrate,
etching the initial oxide layer to create a raised oxide portion in the memory cell region;
forming a high voltage oxide layer on the substrate and the raised oxide portion;
creating a tunnel region in the raised oxide portion; and
forming a low voltage oxide layer in the tunnel.

16. The method of claim 14, wherein forming a first gate in the high voltage device region comprises:
etching the first poly layer to form a first gate in the high voltage device region.

17. The method of claim 16, wherein forming memory cell gates in the memory cell region comprises etching the first poly layer and the second poly layer in the memory cell region.

18. The method of claim 14, wherein forming a plurality of low voltage wells in the high voltage device region comprises adding impurities into the high voltage device region of the substrate.

19. The method of claim 14, wherein removing the second poly layer from the high voltage device region comprises removing the second poly layer from the high voltage device region to form one or more spacers adjacent to the first gate.

20. A nonvolatile memory cell, comprising:
a semiconductor substrate having a high voltage device region, a low voltage device region, and a memory cell region;
a high voltage device formed in the high voltage device region, the high voltage device having a high voltage layer, a first gate, and spacers;
a memory cell formed in the memory cell region, the memory cell having a structured oxide layer, memory cell gates, and a tunnel, wherein the memory cell gates each have a memory cell floating gate and a memory cell control gate; and
a low voltage device formed in the low voltage device region, the low voltage device having a low voltage oxide layer and a second gate, wherein the first gate and the memory cell control gates are formed from a first poly layer and wherein the spacers and second gates are formed from a second poly layer.

21. The nonvolatile memory cell of claim 20, wherein the high voltage device, the memory cell, and the low voltage device are all self-aligned.

22. The nonvolatile memory cell of claim 20, wherein the spacers are adjacent to the first gate.
